(19) United States
(12) Patent Application Publication
(10) Pub. No.: US 2024/0096415 A1
(43) Pub. Date: Mar. 21, 2024

(54) VERTICAL NONVOLATILE MEMORY DEVICE INCLUDING MEMORY CELL STRINGS

(71) Applicant: Samsung Electronics Co., Ltd., Suwon-si (KR)

(72) Inventors: Changseok LEE, Suwon-si (KR); Minhyun LEE, Suwon-si (KR); Seunggeol NAM, Suwon-si (KR)

(73) Assignee: Samsung Electronics Co., Ltd., Suwon-si (KR)

(21) Appl. No.: 18/335,492

(22) Filed: Jun. 15, 2023

(30) Foreign Application Priority Data
Sep. 15, 2022 (KR) 10-2022-0116627

(51) Int. Cl. G11C 16/04; H01L 29/10; H01L 29/18; H01L 29/20; H10B 41/10; H10B 41/27; H10B 41/35; H10B 43/10; H10B 43/27; H10B 43/35

(52) U.S. Cl. CPC G11C 16/0483; H01L 29/1033; H01L 29/18; H01L 29/2003; H10B 41/10; H10B 41/27; H10B 41/35; H10B 43/10; H10B 43/27; H10B 43/35

(57) ABSTRACT

A nonvolatile memory device may include a channel layer extending in a first direction; a plurality of gate electrodes and a plurality of spacers alternately arranged with each other in the first direction, and a gate insulating layer extending in the first direction. Each of the plurality of gate electrodes and each of the plurality of spacers may extend in a second direction crossing the first direction. The gate insulating layer may extend in the first direction. The gate insulating layer may be between the channel layer and the plurality of gate electrodes. The channel layer may include a two-dimensional semiconductor material having an electrically p-type property.

### CROSS-REFERENCE TO RELATED APPLICATION

This application is based on and claims priority under 35 U.S.C. § 119 to Korean Patent Application No. 10-2022-0116627, filed on Sep. 15, 2022, in the Korean Intellectual Property Office, the disclosure of which is incorporated by reference herein in its entirety.

### BACKGROUND

### 1. Field

The present disclosure relates to a vertical nonvolatile memory device including memory cell strings.

### 2. Description of the Related Art

A nonvolatile memory device, which may be a semiconductor memory device, may include a plurality of memory cells that retain data even in a state in which power supply is blocked and may use the stored data again when power is supplied. As examples of use of the nonvolatile memory device, the nonvolatile memory device may be used in a cellular phone, a digital camera, a portable digital assistant (PDA), a mobile computer device, a stationary computer device, and other devices.

Recently, research into using a three-dimensional (or a vertical) NAND (or VNAND) structure in a chip for forming a next-generation neuromorphic computing platform or a neural network has been conducted. In particular, a technology for obtaining high density and low power consumption and allowing random access to a memory cell may be required.

To this end, techniques for realizing a high capacity in the same area by increasing the number of VNAND stacks have been researched. However, when the number of VNAND stacks is increased, a height of a cell region also may be increased as required to match the increase of the stacks, and thus, it may be difficult to obtain a sufficient cell current.

### SUMMARY

Provided is a vertical nonvolatile memory device having an improved cell current by using a material having a high charge mobility as a channel.

Additional aspects will be set forth in part in the description which follows and, in part, will be apparent from the description, or may be learned by practice of the presented embodiments of the disclosure.

According to an embodiment of inventive concepts, a nonvolatile memory device may include a channel layer extending in a first direction; a plurality of gate electrodes and a plurality of spacers alternately arranged with each other in the first direction, each of the plurality of gate electrodes and each of the plurality of spacers extending in a second direction crossing the first direction; and a gate insulating layer extending in the first direction, the gate insulating layer between the channel layer and the plurality of gate electrodes. The channel layer may include a two-dimensional semiconductor material having an electrically p-type property.

In some embodiments, the two-dimensional semiconductor material of the channel layer may include at least one of tellurene, black phosphorus, and WSe₂.

In some embodiments, a hole mobility of the channel layer may be greater than or equal to about 80 cm²/Vs, and an electron mobility of the channel layer may be greater than or equal to about 20 cm²/Vs.

In some embodiments, a thickness of the channel layer in the second direction may be greater than or equal to about 0.3 nm and less than or equal to about 5 nm.

In some embodiments, the nonvolatile memory device may further include an insulating support extending in the first direction. The channel layer may surround the insulating support.

In some embodiments, the nonvolatile memory device may further include a first boron nitride layer between the insulating support and the channel layer. The first boron nitride layer may surround the insulating support and extend in the first direction.

In some embodiments, the first boron nitride layer may include hexagonal boron nitride having a two-dimensional structure or amorphous boron nitride.

In some embodiments, a thickness of the first boron nitride layer in the second direction may be less than or equal to about 5 nm.

In some embodiments, the nonvolatile memory device may further include a second boron nitride layer. The gate insulating layer may surround the channel layer, and the second boron nitride layer may be between the channel layer and the gate insulating layer. The second boron nitride layer may surround the channel layer and the second boron nitride layer may extend in the first direction.

In some embodiments, the gate insulating layer may include a charge blocking layer, a charge trap layer, and a tunneling dielectric layer. The charge blocking layer may be between the channel layer and the plurality of gate electrodes. The charge trap layer may be between the channel layer and the charge blocking layer. The tunneling dielectric layer may be between the channel layer and the charge trap layer.

In some embodiments, the tunneling dielectric layer, the charge trap layer, and the charge blocking layer may extend in the first direction along a surface of the channel layer and may be arranged in a concentric circular shape.

In some embodiments, the nonvolatile memory device may further include a third boron nitride layer between the charge trap layer and the charge blocking layer. The third boron nitride layer may surround the charge trap layer and may extend in the first direction.

In some embodiments, the charge blocking layer and the charge trap layer each may include a first portion extending in the first direction along a surface of the channel layer and a second portion extending in the second direction to cover an upper surface of each of the plurality of gate electrodes and a lower surface of each of the plurality of gate electrodes.

In some embodiments, the tunneling dielectric layer continually may extend in the first direction on an entire side surface of the channel layer.

In some embodiments, the tunneling dielectric layer may include a plurality of tunneling dielectric layers apart from each other, and each of the plurality of tunneling dielectric layers may be between the channel layer and the charge trap layer.

In some embodiments, a side surface of each of the plurality of spacers may directly contact the surface of the channel layer.

In some embodiments, the plurality of gate electrodes may include at least one conductive material. The at least one conductive material may include at least one of W, Mo, Ru, polysilicon, TiN, a metallic two-dimensional material or a combination thereof.

In some embodiments, the metallic two-dimensional material may include at least one of graphene, TaS₂, TaSe₂, NbS₂, NbSe₂, PdTe₂, PtTe₂, NbTe₂, TiSe₂, VSe₂, AuSe, and MoTe₂.

According to an embodiment of inventive concepts, a nonvolatile memory device may include a channel layer extending in a first direction; a plurality of gate electrodes and a plurality of floating gates alternatively arranged with each other in the first direction, each of the plurality of gate electrodes and each of the plurality of floating gates extending in a second direction crossing the first direction; and a gate insulating layer extending in the first direction and arranged between the channel layer and the plurality of gate electrodes. The channel layer may include a two-dimensional semiconductor material having an electrically p-type property. The gate insulating layer may include a tunneling dielectric layer, a charge blocking layer, and a charge trap layer. The tunneling dielectric layer may extend in the first direction along a surface of the channel layer. The charge blocking layer and charge trap layer each may include a first portion extending in the first direction along the surface of the channel layer and a second portion extending in the second direction to cover an upper surface of each of the plurality of gate electrodes and a lower surface of each of the plurality of gate electrodes.

According to an embodiment of inventive concepts, a neuromorphic apparatus may include a processing circuit and a memory system. The memory system may include a nonvolatile memory device and a memory controller configured to perform a control operation on the nonvolatile memory device. The nonvolatile memory device may include a channel layer extending in a first direction, a plurality of gate electrodes and a plurality of spacers alternately arranged with each other in the first direction, and a gate insulating layer extending in the first direction and arranged between the channel layer and the plurality of gate electrodes. Each of the plurality of gate electrodes and each of the plurality of spacers may extend in a second direction crossing the first direction. The channel layer may include a two-dimensional semiconductor material having an electrically p-type property.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of a memory system according to an embodiment;

FIG. 2 is a block diagram of a memory device illustrated in FIG. 1, according to an embodiment;

FIG. 3 is a block diagram of a memory cell array illustrated in FIG. 1;

FIG. 4 is a circuit diagram of an equivalent circuit corresponding to a memory block, according to an embodiment;

FIG. 5 is a schematic vertical cross-sectional view of a structure of a memory cell string, according to an embodiment;

FIG. 6 is a horizontal cross-sectional view schematically illustrating an arrangement of a channel layer and a gate insulating layer of the memory cell string illustrated in FIG. 5;

FIG. 7 is a schematic vertical cross-sectional view of a structure of a memory cell string, according to another embodiment;

FIGS. 8 to 11B are horizontal cross-sectional views schematically illustrating an arrangement of a channel layer and a gate insulating layer of a memory cell string, according to various embodiments;

FIG. 12 is a schematic vertical cross-sectional view of a structure of a memory cell string, according to another embodiment;

FIG. 13 is a schematic vertical cross-sectional view of a structure of a memory cell string, according to another embodiment;

FIG. 14 is a schematic vertical cross-sectional view of a structure of a memory cell string, according to another embodiment; and

FIG. 15 is a schematic block diagram of a neuromorphic apparatus including a memory device, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, a vertical nonvolatile memory device including memory cell strings will be described in detail with reference to the accompanying drawings. In the drawings, the same reference numerals denote the same elements and sizes of elements may be exaggerated for clarity and convenience of explanation. Also, the embodiments described hereinafter are only examples, and various modifications may be made based on the embodiments.

Hereinafter, it will be understood that when an element is referred to as being “on” or “above” another element, the element can be directly over or under the other element and directly on the left or on the right of the other element, or intervening elements may also be present therebetween. As used herein, the singular terms “a” and “an” are intended to include the plural forms as well, unless the context clearly indicates otherwise. It will be further understood that when a part “includes” or “comprises” an element, unless otherwise defined, the part may further include other elements, not excluding the other elements.

The term “the” and other equivalent determiners may correspond to a singular referent or a plural referent. Operations included in a method may be performed in an appropriate order, unless the operations included in the method are described to be performed in an apparent order, or unless the operations included in the method are described to be performed otherwise.

Also, the terms such as “ . . . unit,” “module,” or the like used in the specification indicate a unit, which processes at least one function or motion, and the unit may be implemented by hardware or software, or by a combination of hardware and software.

The connecting lines, or connectors shown in the various figures presented are intended to represent example functional relationships and/or physical or logical couplings between the various elements. It should be noted that many alternative or additional functional relationships, physical connections or logical connections may be present in a practical device.

The use of all examples and example terms are merely for describing the disclosure in detail and the disclosure is not limited to the examples and the example terms, unless they are not defined in the scope of the claims.

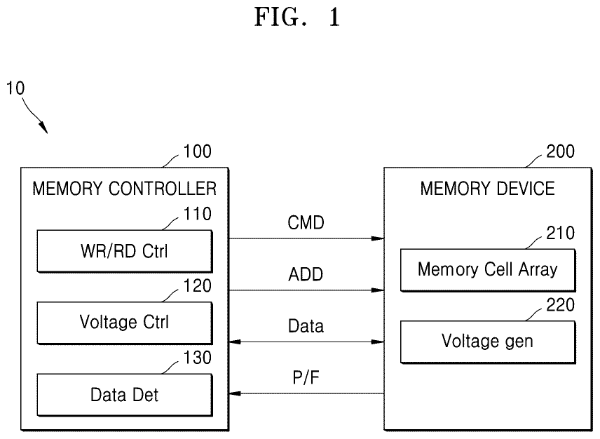

FIG. 1 is a block diagram of a memory system 10 according to an embodiment. Referring to FIG. 1, the memory system 10 according to an embodiment may include a memory controller 100 and a memory device 200. The memory controller 100 may perform a control operation on the memory device 200. For example, the memory controller 100 may provide an address ADD and a command CMD to the memory device 200 to perform a program (or write) operation, a read operation, and an erase operation on the memory device 200. Also, data for the program operation and read data may be transmitted and received between the memory controller 100 and the memory device 200. The memory device 200 may provide a pass/fail signal according to a read result of the read data to the memory controller 100, and the memory controller 100 may control a writing/reading operation of a memory cell array 210 based on the pass/fail signal.

The memory device 200 may include the memory cell array 210 and a voltage generator 220. The memory cell array 210 may include a plurality of memory cells arranged in regions where a plurality of word lines intersect with a plurality of bit lines. The memory cell array 210 may include nonvolatile memory cells storing data in a nonvolatile manner and include flash memory cells, as the nonvolatile memory cells, such as a NAND flash memory cell array or a NOR flash memory cell array. Hereinafter, embodiments of the disclosure will be described in detail on the assumption that the memory cell array 210 includes a flash memory cell array, and thus, the memory device 200 is a nonvolatile memory device.

The memory controller 100 may include a write/read controller 110, a voltage controller 120, and a data determiner 130.

The write/read controller 110 may generate an address ADD and a command CMD for performing programming/reading and erasing operations on the memory cell array 210. Also, the voltage controller 120 may generate a voltage control signal for controlling at least one voltage level used in the nonvolatile memory device 200. For example, the voltage controller 120 may generate a voltage control signal for controlling a voltage level of a word line for reading data from the memory cell array 210 or programming data on the memory cell array 210.

The data determiner 130 may determine the data read from the memory device 200. For example, in order to determine the data read from the memory cells, the data determiner 130 may determine the number of on cells and/or off cells from among the memory cells. As an example of an operation, when program operations are performed on the plurality of memory cells, a state of the data of the memory cells may be determined by using a desired (and/or alternatively predetermined) read voltage, in order to determine whether or not the program operations are normally completed on all of the cells.

As described above, the memory cell array 210 may include nonvolatile memory cells. For example, the memory cell array 210 may include flash memory cells. Also, the flash memory cells may be realized in various forms. For example, the memory cell array 210 may include three-dimensional (or vertical) NAND (or VNAND) memory cells.

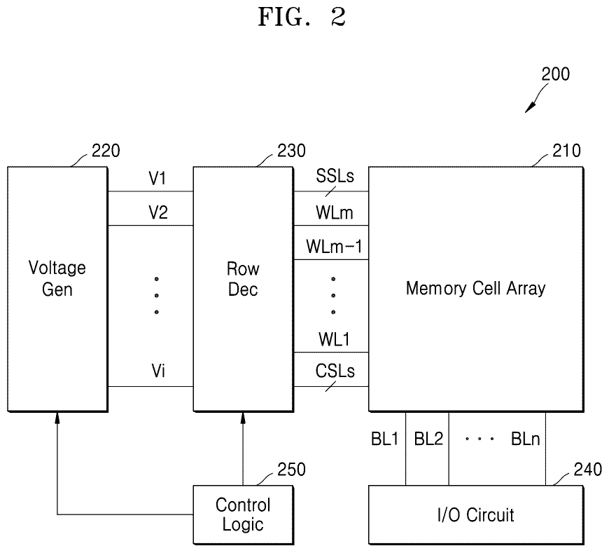

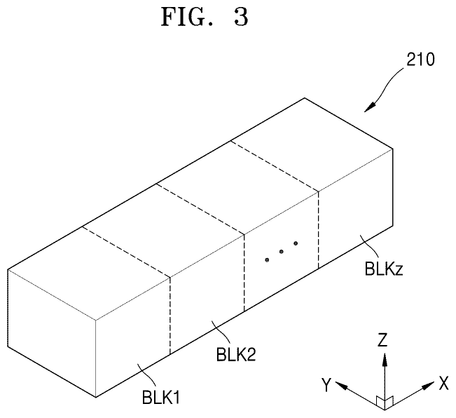

FIG. 2 is a block diagram of the memory device 200 illustrated in FIG. 1, according to an embodiment. Referring to FIG. 2, the memory device 200 may further include a row decoder 230, an input and output circuit 240, and a control logic 250.

The memory cell array 210 may be connected to one or more string selection lines SSLs, a plurality of word lines WL1 through WLm, one or more common source line CSLs, and a plurality of bit lines BL1 through BLn. The voltage generator 220 may generate one or more word line voltages V1 through Vi, and the word line voltages V1 through Vi may be provided to the row decoder 230. Signals for programming/reading/erasing operations may be applied to the memory cell array 210 through the bit lines BL1 through BLn.

Also, data to be programmed may be provided to the memory cell array 210 through the input and output circuit 240, and read data may be provided to the outside (for example, a memory controller) through the input and output circuit 240. The control logic 250 may provide various control signals related to memory operations to the row decoder 230 and the voltage generator 220.

According to a decoding operation of the row decoder 230, the word line voltages V1 through Vi may be provided to various lines SSLs, WL1 through WLm, and CSLs. For example, the word line voltages V1 through Vi may include a string selection voltage, a word line voltage, and a ground selection voltage. The string selection voltage may be provided to one or more string selection lines SSLs, the word line voltage may be provided to one or more word lines WL1 through WLm, and the ground selection voltage may be provided to one or more common source lines CSLs.

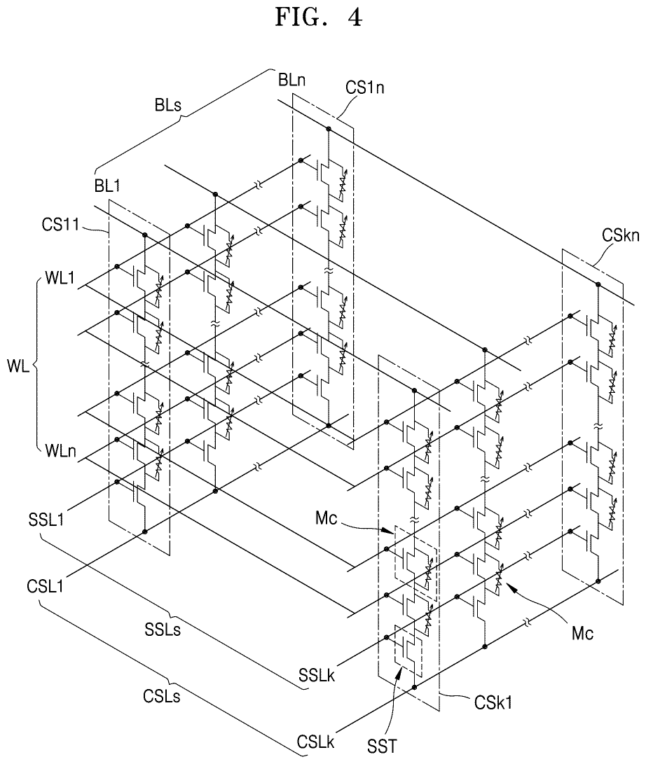

FIG. 3 is a block diagram of the memory cell array 210 illustrated in FIG. 1. Referring to FIG. 3, the memory cell array 210 may include a plurality of memory blocks BLK1 through BLKz. Each of the memory blocks BLK1 through BLKz may have a three-dimensional structure (or a vertical structure). For example, each memory block BLK may include a structure extending in first through third directions. For example, each memory block BLK may include a plurality of memory cell strings extending in the first direction (a Z direction). Also, the plurality of memory cell strings may be two-dimensionally arranged in the second and third directions (X and Y directions). Each memory cell string may be connected to the bit line BL, the string selection line SSL, the word lines WLs, and the common source line CSL. Thus, each of the memory blocks BLK1 through BLKz may be connected to the plurality of bit lines BLs, the plurality of string selection lines SSLs, the plurality of word lines WLs, and the plurality of common source lines CSLs. The memory blocks BLK1 through BLKz will be described in further detail with reference to FIG. 4.

FIG. 4 is a circuit diagram of an equivalent circuit corresponding to a memory block, according to an embodiment. For example, one of the memory blocks BLK1 through BLKz of the memory cell array 210 of FIG. 3 is illustrated in FIG. 4. Referring to FIGS. 3 and 4, each of the memory blocks BLK1 through BLKz may include a plurality of memory cell strings CS11 through CSkn. The plurality of memory cell strings CS11 through CSkn may be two-dimensionally arranged in a row direction and a column direction, thereby forming rows and columns. Each of the memory cell strings CS11 through CSkn may include a plurality of memory cells Mcs and a plurality of string selection transistors SSTs. The memory cells Mcs and the string selection transistors SSTs of each of the memory cell strings CS11 through CSkn may be stacked in a height direction.

Rows of the plurality of memory cell strings CS11 through CSkn may be connected to a plurality of string selection lines SSL1 through SSLk, respectively. For example, the string selection transistors SSTs of the memory cell strings CS11 through CS In may be commonly connected to the string selection line SSL1. The string selection transistors SSTs of the memory cell strings CSkl through CSkn may be commonly connected to the string selection line SSLk.

Also, columns of the plurality of memory cell strings CS11 through CSkn may be connected to the plurality of bit lines BL1 through BLn, respectively. For example, the memory cells Mcs and the string selection transistors SSTs of the memory cell strings CS11 through CSkl may be commonly connected to the bit line BL1, and the memory cells Mcs and the string selection transistors SSTs of the memory cell strings CS1n through CSkn may be commonly connected to the bit line BLn.

Also, the rows of the plurality of memory cell strings CS11 through CSkn may be connected to the plurality of common source lines CSL1 through CSLk, respectively. For example, the string selection transistors SSTs of the plurality of memory cell strings CS11 through CS1n may be commonly connected to the common source line CSL1, and the string selection transistors SST of the plurality of memory cell strings CSkl through CSkn may be commonly connected to the common source line CSLk.

The memory cells MC located at the same height from a substrate (or the string selection transistors SSTs) may be commonly connected to one word line WL, and the memory cells MC located at different heights from the substrate (or the string selection transistors SSTs) may be connected to the plurality of word lines WL1 through WLm, respectively.

The memory block illustrated in FIG. 4 is an example. The disclosure is not limited to the memory block illustrated in FIG. 4. For example, the number of rows of the plurality of memory cell strings CS11 through CSkn may be increased or decreased. When the number of rows of the plurality of memory cell strings CS11 through CSkn is changed, the number of string selection lines connected to the rows of the memory cell strings CS11 through CSkn and the number of memory cell strings CS11 through CSkn connected to one bit line may also be changed. When the number of rows of the memory cell strings CS11 through CSkn is changed, the number of common source lines connected to the rows of the memory cell strings CS11 through CSkn may also be changed. Also, the number of columns of the memory cell strings CS11 through CSkn may be increased or decreased. When the number of columns of the memory cell strings CS11 through CSkn is changed, the number of bit lines connected to the columns of the memory cell strings CS11 through CSkn and the number of memory cell strings CS11 through CSkn connected to one string selection line may also be changed.

A height of each of the memory cell strings CS11 through CSkn may be increased or decreased. For example, the number of memory cells MC stacked in each of the memory cell strings CS11 through CSkn may be increased or decreased. When the number of memory cells MC stacked in each of the memory cell strings CS11 through CSkn is changed, the number of word lines WL may also be changed. For example, the number of string selection transistors SSTs provided to each of the memory cell strings CS11 through CSkn may be increased. When the number of string selection transistors SSTs provided to each of the memory cell strings CS11 through CSkn is changed, the number of string selection lines or the number of common source lines may also be changed. When the number of string selection transistors SSTs is increased, the string selection transistors SSTs may be stacked in a shape that is the same as the shape in which the memory cells MC are stacked.

For example, writing and reading operations may be performed for each row of the memory cell strings CS11 through CSkn. The memory cell strings CS11 through CSkn may be selected for each row by the common source lines CSLs, and the memory cell strings CS11 through CSkn may be selected for each row by the string selection lines SSLs. Also, the writing and reading operations may be performed for each page, in a selected row of the memory cell strings CS11 through CSkn. For example, the page may be one row of the memory cells MC connected to one word line WL. In the selected row of the memory cell strings CS11 through CSkn, the memory cells MCs may be selected for each page by the word lines WL.

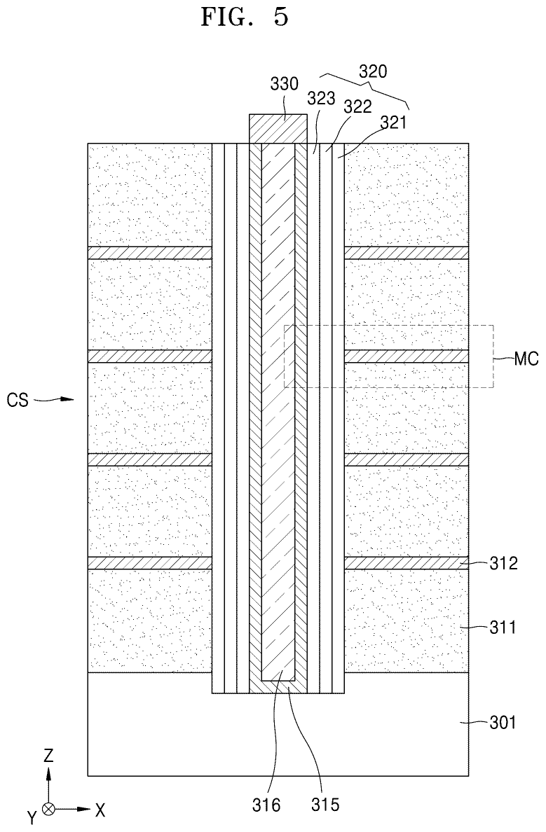

Each of the memory cells MCs in each of the memory cell strings CS11 through CSkn may correspond to a circuit in which a transistor and a resistor are connected in parallel. For example, FIG. 5 is a schematic vertical cross-sectional view of a structure of a memory cell string CS, according to an embodiment. Referring to FIG. 5, the memory cell string CS may include a substrate 301. The substrate 301 may include, for example, a doped silicon material. Also, although not illustrated in detail, the substrate 301 may include a plurality of string selection transistors SSTs, peripheral circuits, etc.

Above the substrate 301, a plurality of insulating spacers 311 extending in a horizontal direction, that is, a second direction (an X direction) parallel with a surface of the substrate 301, and a plurality of gate electrodes 312 extending in the second direction may be alternately arranged. In other words, the memory cell string CS may include the plurality of insulating spacers 311 and the plurality of gate electrodes 312 that are alternately stacked in a vertical direction, that is, a first direction (a Z direction) that is perpendicular to and crosses the second direction. The insulating spacers 311 may include, for example, a silicon oxide, but are not limited thereto. Each of the gate electrodes 312 may be connected to a word line WL, or each of the gate electrodes 312 may be directly a word line WL.

Also, the memory cell string CS may include a channel hole penetrating the plurality of insulating spacers 311 and the plurality of gate electrodes 312 in the first direction. A plurality of layers to form a channel and a resistor may be arranged on an inner side of the channel hole. For example, the memory cell string CS may include an insulating support 316 arranged in a center of the channel hole and extending in the first direction, a channel layer 315 surrounding the insulating support 316 and extending in the first direction, and a gate insulating layer 320 surrounding the channel layer 315 and extending in the first direction. The gate insulating layer 320 may be arranged between the channel layer 315 and the plurality of gate electrodes 312.

The gate insulating layer 320 may include, for example, a charge blocking layer 321, a charge trap layer 322, and a tunneling dielectric layer 323 arranged to extend in the first direction. The charge blocking layer 321 may be arranged between the channel layer 315 and the plurality of gate electrodes 312. The charge trap layer 322 may be arranged between the channel layer 315 and the charge blocking layer 321. The tunneling dielectric layer 323 may be arranged between the channel layer 315 and the charge trap layer 322. Although not shown, the gate insulating layer 320 may further include a diffusion barrier layer arranged between the charge blocking layer 321 and the plurality of gate electrodes 312.

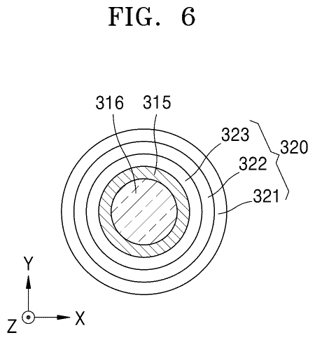

FIG. 6 is a horizontal cross-sectional view schematically illustrating an arrangement of the channel layer 315 and the gate insulating layer 320 of the memory cell string CS illustrated in FIG. 5. Referring to FIG. 6, the insulating support 316, the channel layer 315, and the gate insulating layer 320 may be arranged in a concentric circular shape. In the gate insulating layer 320, the tunneling dielectric layer 323 may have a cylindrical shape surrounding the channel layer 315, the charge trap layer 322 may have a cylindrical shape surrounding the tunneling dielectric layer 323, and the charge blocking layer 321 may have a cylindrical shape surrounding the charge trap layer 322. In other words, the insulating support 316, the channel layer 315, the tunneling dielectric layer 323, the charge trap layer 322, and the charge blocking layer 321 may be arranged in a concentric circular shape.

To this end, the charge blocking layer 321 may be conformally deposited on the plurality of insulating spacers 311 and the plurality of gate electrodes 312 and may extend in the first direction. The charge trap layer 322 may be conformally deposited on a surface of the charge blocking layer 321 and may extend in the vertical direction. The tunneling dielectric layer 323 may be conformally deposited on a surface of the charge trap layer 322 and may extend in the vertical direction. The channel layer 315 may be conformally deposited on a surface of the tunneling dielectric layer 323 and may extend in the vertical direction. The insulating support 316 may be arranged to fill a remaining space of the center of the channel hole and may extend in the vertical direction. Consequently, the charge blocking layer 321, the charge trap layer 322, and the tunneling dielectric layer 323 may have a shape, in which the charge blocking layer 321, the charge trap layer 322, and the tunneling dielectric layer 323 extend on a surface of the channel layer 315 in the first direction.

The tunneling dielectric layer 323 may be a layer in which charge tunneling occurs. When a desired (and/or alternatively predetermined) voltage is applied to each of the gate electrodes 312, a charge flowing through the channel layer 315 may move through the tunneling dielectric layer 323 and may be trapped in the charge trap layer 322, and thus, information may be stored. The charge blocking layer 321 may limit and/or prevent the charge leakage to the insulating spacers 311 and the gate electrodes 312 through the charge trap layer 322. The charge blocking layer 321 may include, for example, at least one of SiO, AlO, MgO, AlN, and GaN, but is not necessarily limited thereto. FIGS. 5 and 6 illustrate, for convenience, that the charge blocking layer 321 is a single layer. However, the charge blocking layer 321 may have a multi-layer structure including different materials. The charge trap layer 322 may include, for example, at least one of SiN, GaN, GaO, HfO, ScO, SrO, ZrO, YO, TaO, BaO, and ZnS, but is not necessarily limited thereto. The tunneling dielectric layer 323 may include, for example, silicon oxide or metal oxide, but is not necessarily limited thereto.

Referring to FIG. 5 again, a drain 330 may be arranged above the memory cell string CS to cover at least the channel layer 315. The drain 330 may include a doped silicon material. The substrate 301 and the drain 330 may be doped to be electrically opposite to each other. For example, when the substrate 301 is doped a p-type, the drain may be doped an n-type. Also, although not shown, a bit line may be connected to the drain 330.

As shown by a box indicated by dashed lines in FIG. 5, any one gate electrode 312, a portion of the gate insulating layer 320 (that is, a portion of the charge blocking layer 321, a portion of the charge trap layer 322, and a portion of the tunneling dielectric layer 323) adjacent to the gate electrode 312 in a horizontal direction, that is, in the second direction, and a portion of the channel layer 315 adjacent to the gate electrode 312 in the second direction may form one memory cell MC. The memory cell MC having this structure may be vertically stacked in a multiple number to form the memory cell string CS. FIG. 5 illustrates that the memory cell MC is configured based on a charge trap flash (CTF) memory using a phase change material. However, the memory cell MC is not necessarily limited thereto. Thus, the structure of the layers arranged on the inner side of the channel hole is only an example and is not limited to the structure illustrated in FIG. 5.

According to an embodiment, the channel layer 315 may include a two-dimensional semiconductor material having a high electron mobility and a high hole mobility. In particular, the channel layer 315 may include a two-dimensional semiconductor material having an electrically p-type property. For example, the channel layer 315 may include at least one two-dimensional semiconductor material from among tellurene, black phosphorus, and WSe₂. Tellurene is a two-dimensional crystal of tellurium. When at least one two-dimensional semiconductor material from among tellurene, black phosphorus, and WSe₂ is used as a material of the channel layer 315, the electron mobility and the hole mobility of the channel layer 315 may be significantly increased compared to a previous case of using polysilicon. For example, the hole mobility of the channel layer 315 may be greater than or equal to about 80 cm²/Vs or greater than or equal to about 100 cm²/Vs, and the electron mobility of the channel layer 315 may be greater than or equal to about 20 cm²/Vs or greater than or equal to about 25 cm²/Vs. Thus, a cell current may be improved in the vertical nonvolatile memory device, a program speed of the vertical nonvolatile memory device may be increased, and the number of stacks of the vertical nonvolatile memory device may further be increased.

Also, compared to the case of using polysilicon, a thickness of the channel layer 315 may be reduced, and thus, a thickness of the charge trap layer 322 may be sufficiently obtained. For example, a thickness of the channel layer 315 in the second direction may be greater than or equal to about 0.3 nm and less than or equal to about 5 nm. Thus, the number of electrons stored in the charge trap layer 322 may be increased, and a fully depleted channel may be realized to improve the threshold voltage distribution.

In particular, tellurene may be deposited at room temperature, chemically stable, and compatible with a general semiconductor manufacturing process. Also, when the channel layer 315 is formed by using tellurene, a high temperature process for crystallizing silicon may not be required, and thus, process costs may be reduced. For example, tellurene may be relatively easily formed by using various processing techniques, such as evaporation, physical vapor deposition (PVD), chemical vapor deposition (CVD), atomic layer deposition (ALD), etc.

Each of the plurality of gate electrodes 312 may include at least one conductive material from among W, Mo, Ru, polysilicon, TiN, and a metallic two-dimensional material or a combination of the materials. The metallic two-dimensional material may include, for example, at least one of graphene, TaS₂, TaSe₂, NbS₂, NbSe₂, PdTe₂, PtTe₂, NbTe₂, TiSe₂, VSe₂, AuSe, and MoTe₂.

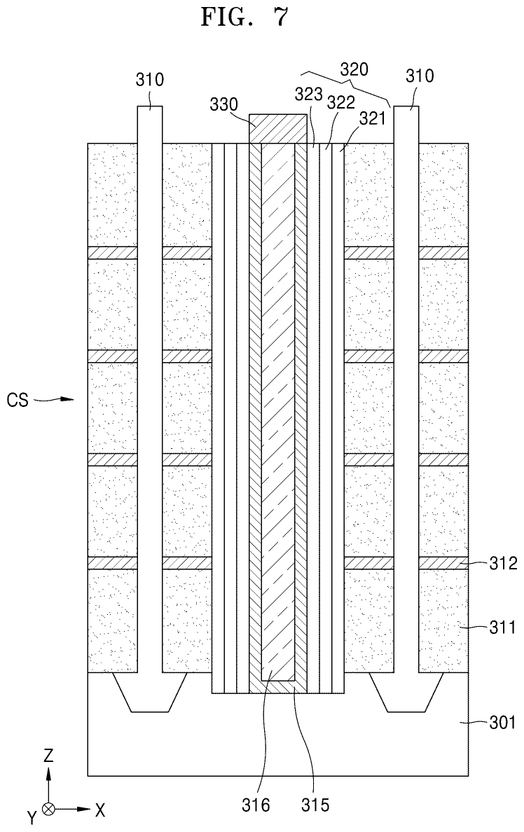

FIG. 7 is a schematic vertical cross-sectional view of a structure of a memory cell string CS, according to another embodiment. Referring to FIG. 7, the memory cell string CS may further include a common source line 310 penetrating the plurality of insulating spacers 311 and the plurality of gate electrodes 312 in the first direction and connected to the substrate 301. The common source line 310 extending in the first direction may be electrically connected to the channel layer 315 through the substrate 301. Although not shown in FIG. 7, the common source line 310 may include an insulating layer surrounding a side surface of the common source line 310 so as not to be electrically connected to the plurality of gate electrodes 312.

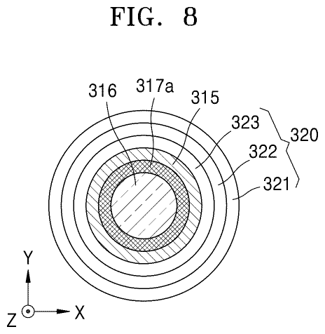

FIGS. 8 to 11B are horizontal cross-sectional views schematically illustrating an arrangement of the channel layer 315 and the gate insulating layer 320 of a memory cell string, according to various embodiments.

Referring to FIG. 8, the memory cell string may further include a first boron nitride layer 317a arranged between the insulating support 316 and the channel layer 315. The first boron nitride layer 317a may be arranged to surround the insulating support 316 and extend in the first direction. Also, the channel layer 315 may be arranged to surround the first boron nitride layer 317a and extend in the first direction. The first boron nitride layer 317a may include, for example, hexagonal boron nitride (h-BN) having a two-dimensional structure or amorphous boron nitride. The first boron nitride layer 317a may prevent or reduce surface distribution of charges on an interface between the insulating support 316 and the channel layer 315 to further enhance the property of the channel layer 315. The first boron nitride layer 317a may be formed as a single two-dimensional layer, and a maximum thickness of the first boron nitride layer 317a in the second direction may be less than or equal to about 5 nm.

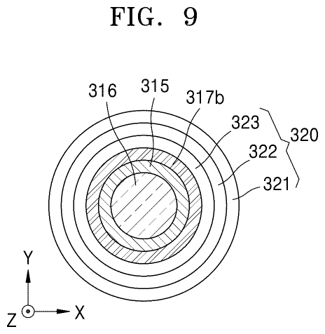

Referring to FIG. 9, the memory cell string may further include a second boron nitride layer 317b arranged between the channel layer 315 and the gate insulating layer 320, in particular, between the channel layer 315 and the tunneling dielectric layer 323. In this case, the second boron nitride layer 317a may be arranged to surround the channel layer 315 and extend in the first direction, and the tunneling dielectric layer 323 may be arranged to surround the second boron nitride layer 317b and extend in the first direction. The second boron nitride layer 317b may include, for example, h-BN having a two-dimensional structure or amorphous boron nitride. The second boron nitride layer 317b may prevent or reduce surface distribution of charges on an interface between the channel layer 315 and the tunneling dielectric layer 323 to further enhance the property of the channel layer 315. Also, the second boron nitride layer 317b may further prevent or reduce the leakage of charges trapped in the charge trap layer 322 through the tunneling dielectric layer 323. The second boron nitride layer 317b may be formed as a single two-dimensional layer, and a maximum thickness of the second boron nitride layer 317b in the second direction may be less than or equal to about 5 nm.

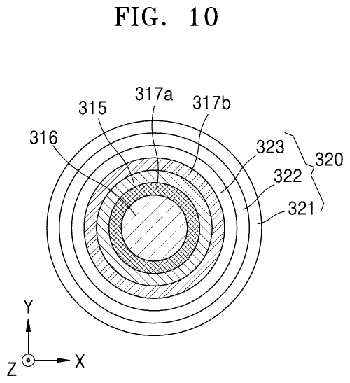

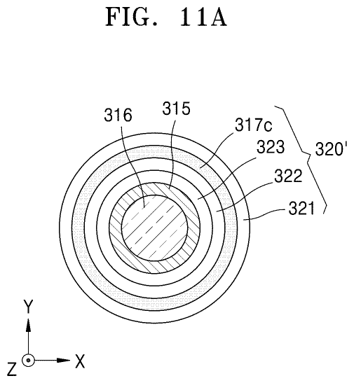

Boron nitride layers may be arranged on both surfaces of the channel layer 315. For example, referring to FIG. 10, the memory cell string may further include the first boron nitride layer 317a arranged between the insulating support 316 and the channel layer 315 and the second boron nitride layer 317b arranged between the channel layer 315 and the tunneling dielectric layer 323.

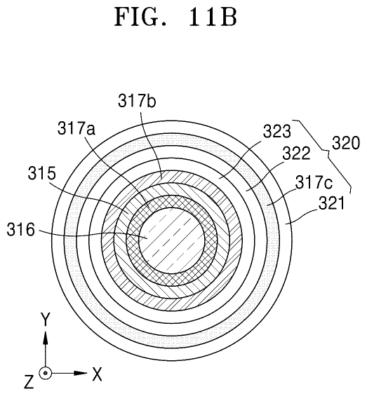

A boron nitride layer may also be arranged in a gate insulating layer to limit and/or prevent the leakage of charges. For example, referring to FIG. 11A, a gate insulating layer 320′ of the memory cell string may further include a third boron nitride layer 317c arranged in the gate insulating layer 320′, in particular, between the charge trap layer 322 and the charge blocking layer 321. In this case, the third boron nitride layer 317c may be arranged to surround the charge trap layer 322 and extend in the first direction, and the charge blocking layer 321 may be arranged to surround the third boron nitride layer 317c and extend in the first direction. The third boron nitride layer 317c may include, for example, h-BN having a two-dimensional structure or amorphous boron nitride. The third boron nitride layer 317c may be formed as a single two-dimensional layer, and a maximum thickness of the third boron nitride layer 317c in the second direction may be less than or equal to about 5 nm. Also, the memory cell string may further include, together with the third boron nitride layer 317c, at least one of the first boron nitride layer 317a and the second boron nitride layer 317b illustrated in FIGS. 8 to 10. For example, as depicted in FIG. 11B, the memory cell string may include the first boron nitride layer 317a between the channel layer 315 and the insulating support 316 and the second boron nitride layer 317b between the channel layer 315 and the tunneling dielectric layer 323. In some embodiments, the first boron nitride layer 317a or the second boron nitride layer 317b may be omitted in the memory cell string of FIG. 11B.

According to these embodiments, the channel layer 315 may include at least one two-dimensional semiconductor material from among tellurene, black phosphorus, and WSe₂, and at least one of the first and second boron nitride layers 317a and 317b for limiting and/or preventing surface distribution of charges on surfaces of the gate electrodes 312 and the channel layer 315 and the third boron nitride layer 317c for limiting and/or preventing the charge leakage in the gate insulating layer 320′ may include a two-dimensional material.

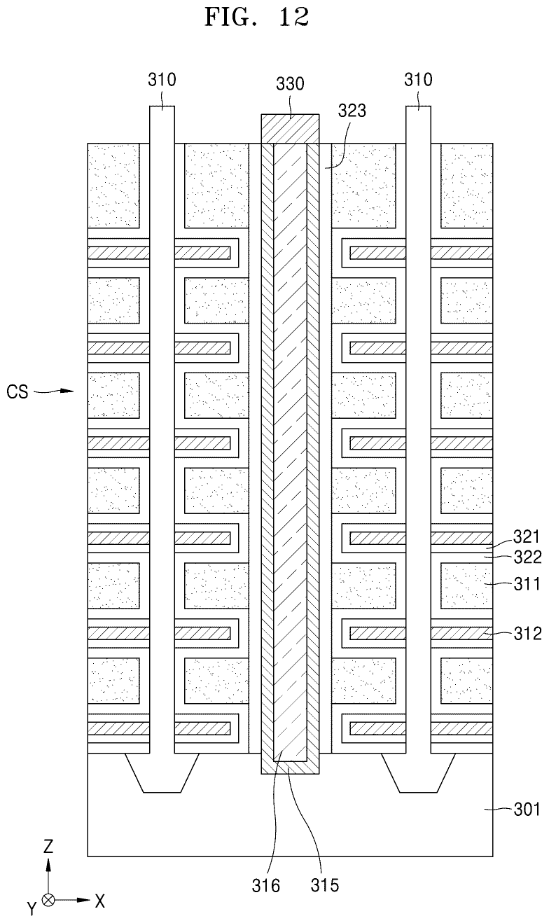

FIG. 12 is a schematic vertical cross-sectional view of a structure of a memory cell string, according to another embodiment. In the embodiments illustrated in FIGS. 5 and 7, all layers of the gate insulating layer 320, that is, the charge blocking layer 321, the charge trap layer 322, and the tunneling dielectric layer 323, may extend in the first direction, and the plurality of gate electrodes 312 may directly contact the insulating spacers 311 respectively adjacent thereto. However, in the embodiment illustrated in FIG. 12, the charge blocking layer 321 and the charge trap layer 322 may be bent to surround an upper surface and a lower surface of each of the plurality of gate electrodes 312. In this case, the charge blocking layer 321 and the charge trap layer 322 may be arranged between the gate electrode 312 and the insulating spacer 311 adjacent to each other. Each of the charge blocking layer 321 and the charge trap layer 322 may include a portion extending in the first direction along a surface of the tunneling dielectric layer 323 and a portion extending in the second direction to cover the upper surface and the lower surface of each of the plurality of gate electrodes 312. In particular, the charge blocking layer 321 may be arranged to surround three surfaces of each gate electrode 312, and the charge trap layer 322 may be arranged to surround three surfaces of the charge blocking layer 321. Also, the charge trap layer 322 may further extend in the first direction along a surface of the common source line 310.

The tunneling dielectric layer 323 may extend in the first direction along the surface of the channel layer 315. A side surface of each of the plurality of insulating spacers 311 may directly contact the surface of the tunneling dielectric layer 323. Another side surface, an upper surface, and a lower surface of each of the plurality of insulating spacers 311 may be surrounded by the charge trap layer 322. Thus, the charge trap layer 322 may have a serpentine shape along the three surfaces of each insulating spacer 311, the side surface of the common source line 310, and the three surfaces of the charge blocking layer 321.

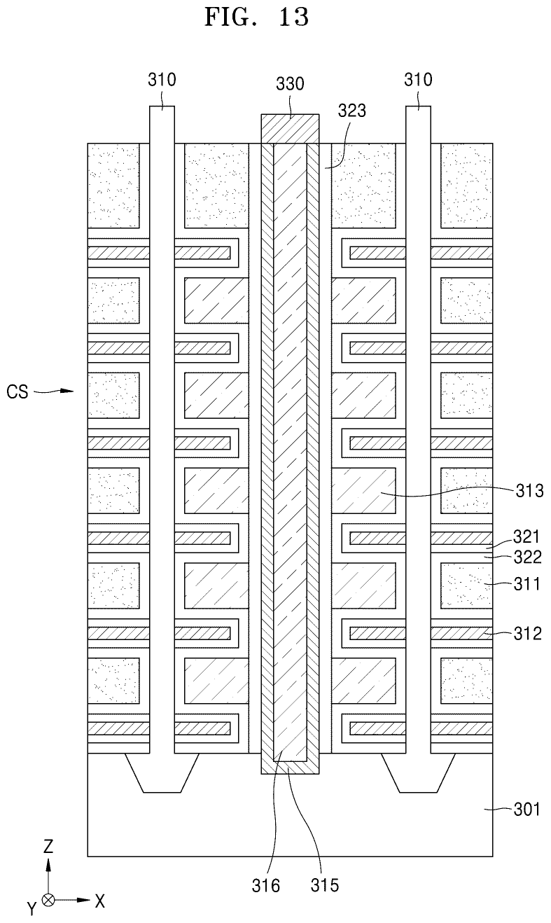

FIG. 13 is a schematic vertical cross-sectional view of a structure of a memory cell string, according to another embodiment. Referring to FIG. 13, the memory cell string may include, rather than the plurality of insulating spacers 311, a plurality of floating gates 313 arranged in a region surrounded by the tunneling dielectric layer 323 and the charge trap layer 322. In other words, the plurality of gate electrodes 312 extending in the second direction and the plurality of floating gates 313 extending in the second direction may be alternately arranged in the first direction. The charge blocking layer 321 and the charge trap layer 322 may be arranged between the gate electrode 312 and the floating gate 313 adjacent to each other. A side surface of each floating gate 313 may directly contact a surface of the tunneling dielectric layer 323, and another side surface, an upper surface, and a lower surface of the floating gate 313 may be surrounded by the charge trap layer 322. In this case, two gate electrodes 312 respectively facing the upper surface and the lower surface of each floating gate 313 may function as control gates.

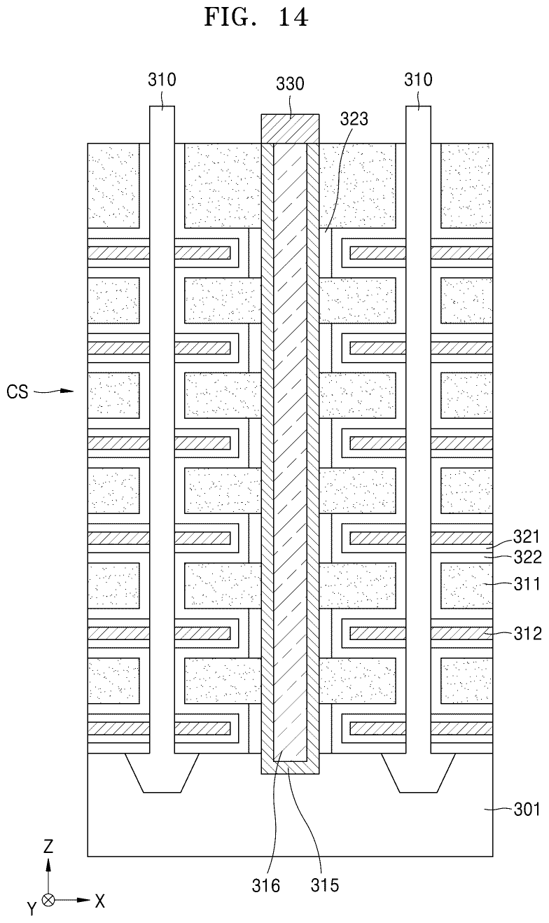

FIG. 14 is a schematic vertical cross-sectional view of a structure of a memory cell string, according to another embodiment. In the case of the embodiment illustrated in FIG. 12, one tunneling dielectric layer 323 may continually extend in the first direction on the entire side surface of the channel layer 315. However, a memory cell string is not necessarily limited thereto. Referring to FIG. 14, a plurality of tunneling dielectric layers 323 apart from each other may be arranged along the channel layer 315. For example, each of the plurality of tunneling dielectric layers 323 may be arranged only between the channel layer 315 and the charge trap layer 322. In this case, a side surface of each of the plurality of insulating spacers 311 may directly contact a surface of the channel layer 315.

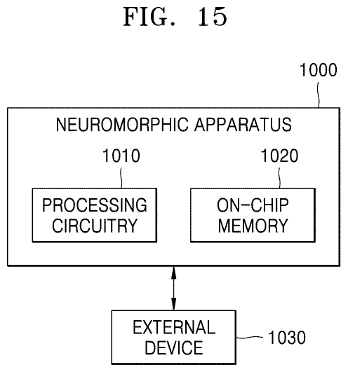

A memory block according to the embodiment described above may be realized in the form of a chip and may be used as a neuromorphic computing platform. For example, FIG. 15 is a schematic view of a neuromorphic apparatus 1000 including a memory device, according to an embodiment. Referring to FIG. 15, the neuromorphic apparatus 1000 may include a processing circuitry 1010 and/or a memory 1020. The memory 1020 of the neuromorphic apparatus 1000 may include the memory system 10 according to an embodiment.

Processing circuitry 1010 may be configured to control functions for driving the neuromorphic apparatus 1000. For example, the processing circuitry 1010 may be configured to control the neuromorphic apparatus 1000 by executing programs stored in the memory 1020 of the neuromorphic apparatus 1000. The processing circuitry 1010 may include hardware such as logic circuits; a hardware/software combination, such as a processor executing software; or a combination thereof. For example, a processor may include, but is not limited to, a central processing unit (CPU), a graphics processing unit (GPU), an application processor (AP) included in the neuromorphic apparatus 1000, an arithmetic logic unit (ALU), a digital signal processor, a microcomputer, a field programmable gate array (FPGA), a system-on-chip (SoC), a programmable logic unit, a microprocessor, an application-specific integrated circuit (ASIC), or the like. Also, the processing circuitry 1010 may be configured to read/write a variety of data from/in an external device 1030 and/or execute the neuromorphic apparatus 1000 by using the read/written data. The external device 1030 may include an external memory and/or sensor array with an image sensor (e.g., a CMOS image sensor circuit).

The neuromorphic apparatus 1000 in FIG. 15 may be applied in a machine learning system. The machine learning system may utilize a variety of artificial neural network organizational and processing models, such as convolutional neural networks (CNN), de-convolutional neural networks, recurrent neural networks (RNN) optionally including long short-term memory (LSTM) units and/or gated recurrent units (GRU), stacked neural networks (SNN), state-space dynamic neural networks (SSDNN), deep belief networks (DBN), generative adversarial networks (GANs), and/or restricted Boltzmann machines (RBM).

Such machine learning systems may include other forms of machine learning models, such as, for example, linear and/or logistic regression, statistical clustering, Bayesian classification, decision trees, dimensionality reduction such as principal component analysis, and expert systems; and/or combinations thereof, including ensembles such as random forests. Such machine learning models may be used to provide various services, for example, an image classify service, a user authentication service based on bio-information or biometric data, an advanced driver assistance system (ADAS) service, a voice assistant service, an automatic speech recognition (ASR) service, or the like, and may be mounted and executed by other electronic devices.

The vertical nonvolatile memory device including the memory cell string are described above according to embodiments illustrated in the drawings. However, the descriptions are only examples, and one of ordinary skill in the art may understand that various modifications and equivalent embodiments are possible from the descriptions.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A nonvolatile memory device comprising:
a channel layer extending in a first direction;
a plurality of gate electrodes and a plurality of spacers alternately arranged with each other in the first direction, each of the plurality of gate electrodes and each of the plurality of spacers extending in a second direction crossing the first direction; and
a gate insulating layer extending in the first direction, the gate insulating layer between the channel layer and the plurality of gate electrodes,
wherein the channel layer includes a two-dimensional semiconductor material having an electrically p-type property.

2. The nonvolatile memory device of claim 1, wherein the two-dimensional semiconductor material of the channel layer includes at least one of tellurene, black phosphorus, and WSe₂.

3. The nonvolatile memory device of claim 1, wherein
a hole mobility of the channel layer is greater than or equal to about 80 cm²/Vs, and
an electron mobility of the channel layer is greater than or equal to about 20 cm²/Vs.

4. The nonvolatile memory device of claim 1, wherein a thickness of the channel layer in the second direction is greater than or equal to about 0.3 nm and less than or equal to about 5 nm.

5. The nonvolatile memory device of claim 1, further comprising:
an insulating support extending in the first direction, wherein
the channel layer surrounds the insulating support.

6. The nonvolatile memory device of claim 5, further comprising:
a first boron nitride layer between the insulating support and the channel layer, wherein
the first boron nitride layer surrounds the insulating support and extends in the first direction.

7. The nonvolatile memory device of claim 6, wherein
the first boron nitride layer includes hexagonal boron nitride having a two-dimensional structure or amorphous boron nitride.

8. The nonvolatile memory device of claim 6, wherein a thickness of the first boron nitride layer in the second direction is less than or equal to about 5 nm.

9. The nonvolatile memory device of claim 1, further comprising:
a second boron nitride layer, wherein
the gate insulating layer surrounds the channel layer,
the second boron nitride layer is between the channel layer and the gate insulating layer,
the second boron nitride layer surrounds the channel layer, and
the second boron nitride layer extends in the first direction.

10. The nonvolatile memory device of claim 1, wherein
the gate insulating layer includes a charge blocking layer, a charge trap layer, and a tunneling dielectric layer,
the charge blocking layer is between the channel layer and the plurality of gate electrodes,
the charge trap layer is between the channel layer and the charge blocking layer, and
the tunneling dielectric layer is between the channel layer and the charge trap layer.

11. The nonvolatile memory device of claim 10, wherein
the tunneling dielectric layer, the charge trap layer, and the charge blocking layer extend in the first direction along a surface of the channel layer and are arranged in a concentric circular shape.

12. The nonvolatile memory device of claim 11, further comprising:
a third boron nitride layer between the charge trap layer and the charge blocking layer, wherein
the third boron nitride layer surrounds the charge trap layer, and
the third boron nitride layer extends in the first direction.

13. The nonvolatile memory device of claim 10, wherein
the charge blocking layer and the charge trap layer each include a first portion extending in the first direction along a surface of the channel layer and a second portion extending in the second direction to cover an upper surface of each of the plurality of gate electrodes and a lower surface of each of the plurality of gate electrodes.

14. The nonvolatile memory device of claim 13, wherein the tunneling dielectric layer continually extends in the first direction on an entire side surface of the channel layer.

15. The nonvolatile memory device of claim 13, wherein
the tunneling dielectric layer includes a plurality of tunneling dielectric layers apart from each other, and
each of the plurality of tunneling dielectric layers are between the channel layer and the charge trap layer.

16. The nonvolatile memory device of claim 15, wherein a side surface of each of the plurality of spacers directly contacts the surface of the channel layer.

17. The nonvolatile memory device of claim 1, wherein
the plurality of gate electrodes include at least one conductive material, and
the at least one conductive material includes at least one of W, Mo, Ru, polysilicon, TiN, a metallic two-dimensional material or a combination thereof.

18. The nonvolatile memory device of claim 17, wherein the metallic two-dimensional material includes at least one of graphene, TaS₂, TaSe₂, NbS₂, NbSe₂, PdTe₂, PtTe₂, NbTe₂, TiSe₂, VSe₂, AuSe, and MoTe₂.

19. A nonvolatile memory device comprising:
a channel layer extending in a first direction;
a plurality of gate electrodes and a plurality of floating gates alternately arranged with each other in the first direction, each of the plurality of gate electrodes and each of the plurality of floating gates extending in a second direction, the second direction crossing the first direction; and
a gate insulating layer extending in the first direction and arranged between the channel layer and the plurality of gate electrodes, wherein
the channel layer includes a two-dimensional semiconductor material having an electrically p-type property,
the gate insulating layer includes a tunneling dielectric layer, a charge blocking layer, and a charge trap layer,
the tunneling dielectric layer extending in the first direction along a surface of the channel layer, and
the charge blocking layer and the charge trap layer each include a first portion extending in the first direction along the surface of the channel layer and a second portion extending in the second direction to cover an upper surface of each of the plurality of gate electrodes and a lower surface of each of the plurality of gate electrodes.

20. A neuromorphic apparatus comprising:
a processing circuit; and
a memory system including a nonvolatile memory device and a memory controller configured to perform a control operation on the nonvolatile memory device, wherein
the nonvolatile memory device includes
a channel layer extending in a first direction,
a plurality of gate electrodes and a plurality of spacers alternately arranged with each other in the first direction, and
a gate insulating layer extending in the first direction and arranged between the channel layer and the plurality of gate electrodes,
each of the plurality of gate electrodes and each of the plurality of spacers extend in a second direction crossing the first direction, and
the channel layer includes a two-dimensional semiconductor material having an electrically p-type property.
